(19) United States
(12) Patent Application Publication
(10) Pub. No.: US 2007/0111112 A1
(43) Pub. Date: May 17, 2007

(54) Systems and methods for fabricating photo masks

(75) Inventors: Sung-Min Huh, Yongin-si (KR); Hee-Bom Kim, Suwon-si (KR); Seong-Woon Choi, Suwon-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/598,754

(22) Filed: Nov. 14, 2006

(30) Foreign Application Priority Data
Nov. 15, 2005 (KR) 10-2005-0109253

(51) Int. Cl. G03F 1/00

(52) U.S. Cl. 430/5

(57) ABSTRACT

A system and method for fabricating a photo mask are provided. The method includes preparing weak point data based on mask layout data, fabricating a photo mask based on the mask layout data and extracting critical point data by analyzing the aerial image of the fabricated photo mask based on the weak point data.

### PRIORITY STATEMENT

This non-provisional U.S. patent application claims priority under 35 U.S.C. § 119 to Korean Patent Application No. 2005-0109253, filed on Nov. 15, 2005, in the Korean Intellectual Property Office (KIPO), the entire contents of which are incorporated herein by reference.

### BACKGROUND

### Description of the Related Art

Related art lithography techniques for fabricating semiconductor devices involve transferring a pattern formed on a photo mask to a wafer through an optical lens. However, as integration density of semiconductor devices increases, the size of mask patterns may be approximated to the wavelength of a light source. As a result, related art lithography techniques are increasingly affected by diffraction and/or interference of light. For example, because an optical system for projecting an image functions as a low-pass filter, a photoresist pattern formed on a wafer may be distorted from an original shape of a mask pattern, as shown in FIGS. 1A and 1B.

If the size (or period) of the mask pattern is relatively large, spatial frequency may be relatively low, and thus, light with various frequencies may be transmitted through the mask pattern. As a result, an image relatively similar to the original pattern may be formed on the wafer. However, a portion of photo mask with a higher spatial frequency (e.g. an edge) may be distorted in a rounded shape. This distortion of an image is referred to as an optical proximity effect (OPE). As the pattern size is reduced, the spatial frequency may increase, such that the number of frequencies transmitted may be reduced. This may worsen the distortion of an image due to OPE.

Optical proximity correction (OPC) techniques may be used to suppress OPE. In an example related art OPC technique, the shape of a mask pattern is changed to correct the image distortion. OPC may lead to improvements in optical resolution and/or pattern transfer fidelity. OPC requires the use of methods of adding/removing sub-resolution fine patterns to/from a mask pattern formed on a photo mask, for example, line-end treatment or insertion of scattering bars. The line-end treatment may include adding a corner Serif pattern or a hammer pattern to overcome the rounding of an end portion of a line pattern as shown in FIG. 2A. The insertion of scattering bars may include adding sub-resolution scattering bars around a target pattern so as to reduce pitch variation on patterns with respect to pattern density as shown in FIG. 2B.

A layout process may be followed by design rule checks (DRC), electrical rule checks (ERC), electrical parameter extraction (EPE) and layout versus schematic (LVS) verification.

OPC programs may be categorized as either a rule-based method processing layout data under some rules prepared from lithography engineers' experience or a model-based method in which a layout is modified based on the mathematical model of a lithography system.

In an example rule-based method, several rules that a pattern is partially cut or a small subsidiary pattern is added may be made beforehand and a layout may be modified based on the rules. The rule-based method may have a faster operating speed because layout data corresponding to the entire region of a chip may be processed simultaneously. However, trial and error may be necessary to apply this rule-based method to a new lithography process adopting different lithography apparatuses and/or a new illumination technique. Therefore, new rules requiring many experiments need be made for each generation. Also, because the rule-based OPC technique does not correct the layout based on simulation results, a pattern formed on a wafer may not be as precise.

In another example, a model-based method adopts the mathematical model of an optical lithography system to correct the deformation of a mask pattern by applying the model of the lithography system to a negative feedback system. Because this model-based method is based on repeated calculation, required operating time may be relatively large. Thus, the model-based method may be applied to only a relatively small amount of data. However, the model-based method may provide an optimized OPC result irrespective of the shapes of patterns. Further, the model-based method may find a solution where a rule-set cannot be applied, and be used to obtain a rule-set of a rule-based program. Thus, an optimal solution may be provided for various patterns with only a few experiments. As a result, when an optimal solution is required irrespective of time, for example, in the case of a memory cell, the model-based OPC method may be used.

FIG. 3 is a process flow chart illustrating a related art method of fabricating a photo mask including an OPC operation.

Referring to FIG. 3, mask layout data 40 defining the layout of patterns to be formed on a photo mask may be produced using integrated circuit (IC) layout data 20 defining the layout of an IC. The mask layout data 40 may be produced through an OPC operation 30 of correcting the IC layout data 20 using an OPC model 10. In this example, the mask layout data 40 corresponds to a result obtained by correcting the IC layout data 20 to overcome the distortion of images due to an OPE.

Thereafter, a photo mask is fabricated based on the mask layout data 40 in operation 60 and evaluated on a wafer level in operation 80. The wafer-level evaluation 80 of the fabricated photo mask is a process of ascertaining if real patterns formed on a wafer through a lithography process using the fabricated photo mask have a desired shape.

The related art method may also include extracting weak point data 70 defining information on weak points by performing an optical rule check (ORC) 50 to evaluate the appropriateness of the OPC operation. The weak point data 70 includes layout information on weak points at which a predicted photo mask layout falls short of or fails a threshold standard, and is used as input data in the wafer-level evaluation 80 for evaluating the fabricated photo mask in terms of pattern transfer fidelity.

However, the weak point data 70 may not provide sufficiently precise information on weak points for various reasons. For example, the accuracy of the weak point data 70 may depend on the appropriateness of the OPC model 10 used for the OPC operation 30, the occurrence of mask mean-to-target (MTT) during the fabrication of the photo mask, global and/or local CD uniformity and/or a mask topology effect. However, considering that the weak point data 70 is obtained by analyzing a simulation based on the mask layout data 40 instead of analyzing a real photo mask, solving the inaccuracy of the weak point data 70 may be difficult.

Furthermore, because the wafer-level evaluation 80 involves manually detecting weak points defined by the weak point data 70, when a large number of weak points are defined, the efficiency of the wafer-level evaluation 80 may deteriorate. For example, when the fabricated photo mask does not satisfy conditions in the wafer-level evaluation 80, the photo mask is discarded and a new photo mask may be fabricated. The fabrication of the new photo mask includes operations 2 and 4 of correcting the OPC model 10 or the IC layout data 20 to satisfy the conditions. However, obtaining the result of the wafer-level evaluation 80 after the fabrication of the photo mask, a decision on whether a new photo mask may take a month or more, is to be fabricated may be delayed.

Related art methods of fabricating photo masks brings about inaccuracy of the weak point data 70, inefficiency of the wafer-level evaluation 80 and a delay in the decision on whether to fabricate a new photo mask.

### SUMMARY

Example embodiments relate to systems and methods for fabricating a photo mask. At least some example embodiments provide systems and methods for fabricating a photo mask that may increase accuracy of weak point data, efficiency of wafer-level evaluation and/or more rapidly determine if fabrication of a new photo mask is necessary.

According to at least one example embodiment, a method of fabricating a photo mask may include generating or preparing mask layout data defining the layout of patterns formed on a photo mask. Weak point data for defining information on predicted weak points of a photo mask to be fabricated may be generated or prepared based on the mask layout data. The photo mask may be fabricated based on the mask layout data. An aerial image of the fabricated photo mask may be analyzed based on the weak point data to extract critical point data defining information on weak points of the fabricated photo mask.

According to at least one example embodiment, the preparing of the mask layout data may include preparing integrated circuit (IC) layout data defining the layout of an IC, and performing an optical proximity correction (OPC) operation on the IC layout data using an OPC model. In at least some example embodiments, the preparing of the mask layout data may further include phase-shift mask (PSM) processing the IC layout data. The preparing of the weak point data may include predicting the layout of the photo mask using the mask layout data and extracting the weak point data by comparing the predicted layout of the photo mask with the IC layout data and analyzing the comparison result. The weak point data may include information on the coordinates, pattern sizes and/or size margins of points violating an optical rule.

According to at least some example embodiments, analyzing of the aerial image of the photo mask may be performed using an aerial image measurement system (AIMS) including a communication apparatus capable of accessing the weak point data to make use of the weak point data as input data. The generating or extracting of the critical point data may include extracting information on the coordinates, pattern sizes and/or size margins of points violating an optical rule by comparing the aerial image of the photo mask with the IC layout data, and analyzing the comparison result at weak points defined by the weak point data.

According to at least some example embodiments, the quality of the photo mask may be evaluated by analyzing the critical point data, and/or the quality of the photo mask on a wafer level may be evaluated through a lithography process using the photo mask. In this example, when quality of the photo mask falls below of a threshold, at least one of the OPC model and the IC layout data may be updated using at least one of the weak point data, the critical point data and the aerial image of the photo mask. When quality of the photo mask on the wafer level falls below a threshold standard, at least one of the OPC model and the IC layout data may be updated using at least one of the weak point data, the critical point data and the aerial image of the photo mask.

When quality of the photo mask on the wafer level passes the threshold standard, a lithography process may be performed using the fabricated photo mask. The critical point data may be used as data for defining inspection positions during an inspection on the result of the lithography process.

According to at least some example embodiments, a photo mask fabrication system may include at least one database (e.g., a first, second and/or third) database for storing IC layout data and/or mask layout data, an OPC apparatus for performing an OPC operation on the IC layout data to generate the mask layout data, a weak point analysis apparatus for extracting weak point data based on the mask layout data and/or a critical point analysis apparatus for extracting critical point data based on the weak point data.

In at least some example embodiments, the weak point analysis apparatus may include a simulator for predicting the layout of a photo mask to be fabricated based on the mask layout data, and a weak point data extracting unit for comparing the predicted layout of the photo mask with the IC layout data and analyzing the comparison result to extract the weak point data. The weak point analysis apparatus may be connected to the at least one database through at least one communication apparatus. The critical point analysis apparatus may include an AIMS for measuring the aerial image of the photo mask based on the mask layout data and a critical point data extracting unit for comparing the aerial image with the IC layout data and analyzing the comparison result. The critical point data extracting unit may selectively compare the aerial image with the IC layout data and analyze the comparison result at weak points defined by the weak point data.

### BRIEF DESCRIPTION OF THE DRAWINGS

The accompanying drawings, which are included to provide a further understanding of example embodiments and are incorporated in and constitute a part of this application, illustrate example embodiments. In the drawings:

FIGS. 1A and 1B are photographs showing an example of a related art optical proximity effect;

FIG. 2A illustrates an example of related art line-end treatment for optical proximity correction (OPC);

FIG. 2B illustrates an example of related art insertion of scattering bars for OPC;

FIG. 3 is a process flow chart illustrating a related art method of fabricating a photo mask including an OPC operation;

FIG. 4 is a process flow chart illustrating a method of fabricating a photo mask, according to an example embodiment;

FIG. 5 is a photograph showing an example, aerial image of a photo mask, formed using a method, according to an example embodiment;

FIG. 6 is a photograph showing example results obtained by analyzing a process margin using the aerial image shown in FIG. 5;

FIG. 7 is a graph illustrating an example method of analyzing data, according to an example embodiment; and

FIG. 8 is an apparatus construction diagram illustrating a photo mask fabrication system, according to an example embodiment.

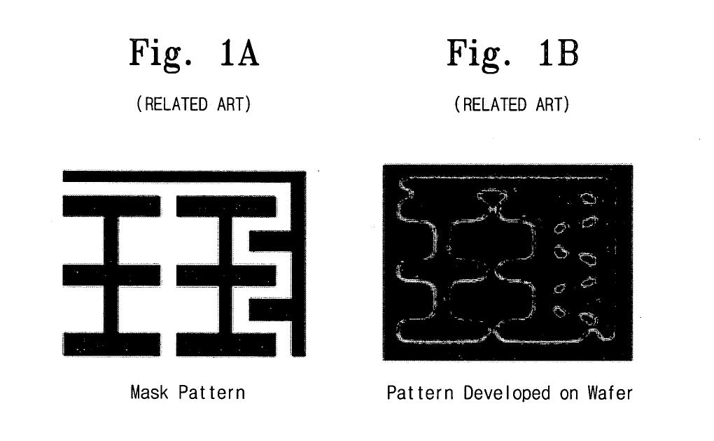

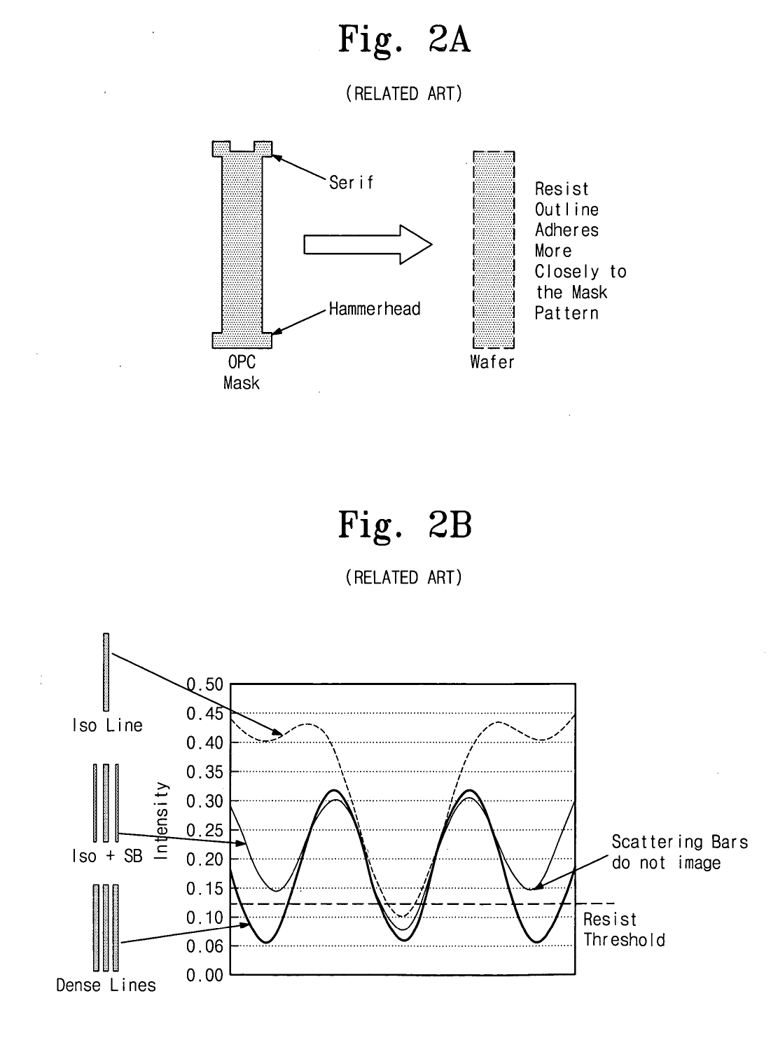

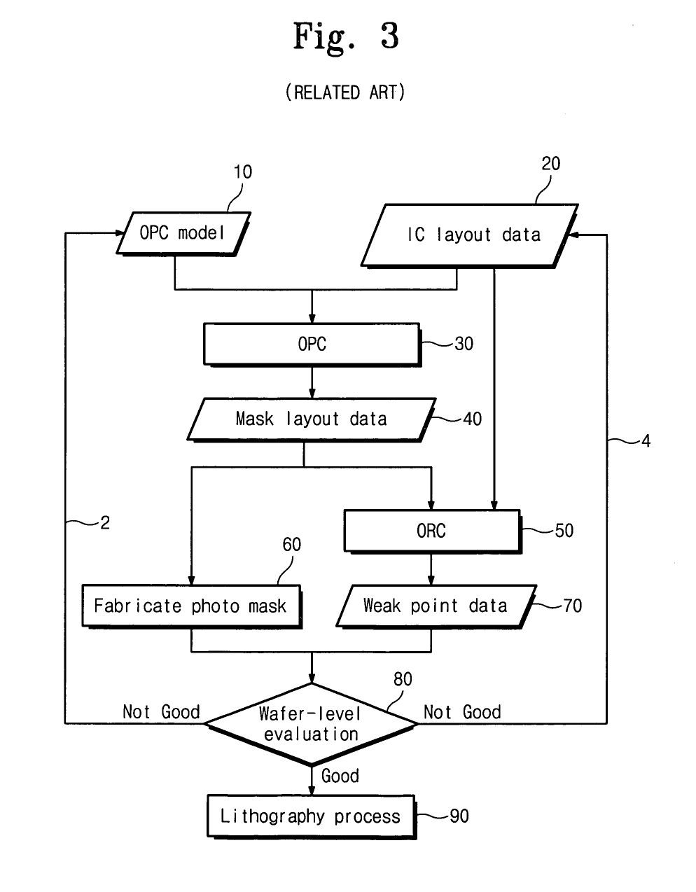

### DETAILED DESCRIPTION OF EXAMPLE EMBODIMENTS

Reference will now be made in detail to the example embodiments illustrated in the accompanying drawings. However, example embodiments are not limited to those shown in the drawings, but rather are introduced to provide easy and complete understanding of the scope and spirit of the present invention. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g.,. “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

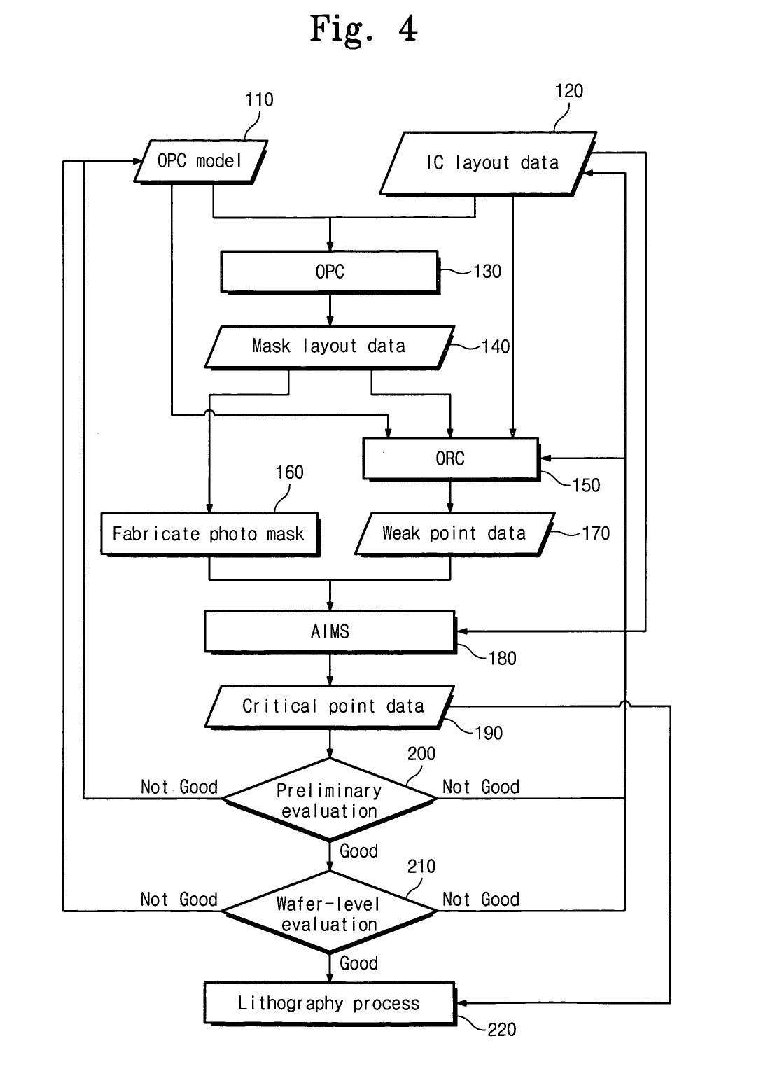

FIG. 4 is a process flow chart illustrating a method of fabricating a photo mask, according to an example embodiment.

Referring to FIG. 4, mask layout data 140 may be produced based on integrated circuit (IC) layout data 120. The IC layout data 120 may include data (e.g., GDS II) in a format suitable for defining a target pattern to be printed on a wafer. The mask layout data 140 may be data (e.g., GDS II) in a format suitable for defining a mask pattern to be formed on a photo mask. The mask layout data 140 may be used to print the target pattern defined by the IC layout data 120. The mask layout data 140 may be produced using, for example, an optical proximity correction (OPC) process 130. In the OPC process 130, the IC layout data 120 may be corrected using an OPC model 110.

The OPC model 110 may be generated (e.g., created) based on measured data and/or experimental process parameter data. The OPC model 110 may be used to evaluate effects of a lithography process encountered during printing of the target pattern. The measured data may be obtained by analyzing resultant structures printed on the wafer using a test mask including patterns with various shapes. In this example, a test mask, corresponding to various shapes and arrangements of real patterns (e.g., target patterns) formed on an IC, may be prepared. For example, the test mask may be constructed to monitor diverse optical proximity effects (OPEs). The test mask may include line-end type test patterns, line and space type test patterns, isolated bar type test patterns and/or isolated space type test patterns. However, these types of test patterns may be varied as desired, and example embodiments are not limited to the above-described example test patterns.

The experimental process parameter data may be data regarding process parameters affecting a lithography process and/or an etching process. The experimental process data may quantitatively express results of the lithography and/or etching process with respect to the process parameters. For example, the process parameter data may contain information on an illumination system and may be collected over a period of time in at least one or a plurality of experiments. User input may also be considered in determining process parameter data. OPC models may constitute a multi-dimensional database based on the process parameter data. In at least one example embodiment, one multi-dimensional model may be used as the OPC model 110 for the OPC process 130. Similarly, the dimensions and/or items of the database may be varied as desired.

The preparation of the mask layout data 140 may also include a phase-shift mask (PSM) processing operation. In a PSM processing operation, a PSM region may be defined in the IC layout data 120. The PSM region may enable features with a smaller dimension than the wavelength of light passing through the photo mask to be printed on the target pattern.

Referring still to FIG. 4, Weak point data 170 may be extracted using an optical rule check (ORC) operation 150. The ORC operation 150 may include predicting the layout of a photo mask to be fabricated based on the mask layout data 140, comparing the predicted layout with the IC layout data 120 to generate a comparison result and analyzing the comparison result. The layout of the photo mask to be fabricated may be predicted by a simulation using the mask layout data 140 as input data. The weak point data 170 may include layout data on weak points at which the predicted layout of the photo mask falls short of or fails a threshold standard. For example, the weak points may be defined as points at which a difference between the predicted layout of the photo mask and the IC layout data 120 is greater than or equal to a threshold value. The layout data may include the coordinates of the weak points, pattern sizes and/or size margins. The threshold standard for the weak points and/or the substance of the layout data may be varied as desired.

A photo mask fabrication operation 160 may be performed concurrently with the ORC operation 150 and/or the weak point data operation 170. During the photo mask fabrication operation 160, a photo mask may be fabricated using the mask layout data 140. In at least this example embodiment, mask patterns may be formed by patterning a mask layer formed on a substrate using electronic beams and a region irradiated with the electronic beams may be determined based on the mask layout data 140. The substrate may be, for example, a glass, plastic, quartz or silicon substrate, and the mask layer may be a chrome (Cr) layer; however, other suitable substrates may be used.

During the photo mask fabrication operation 160, the formed mask patterns may be different from the mask patterns defined by the mask layout data 140 because of process deviations caused by electronic or electron beam irradiation and/or subsequent etching processes. In at least one example, the predicted layout of the photo mask used in the ORC operation 150 may be different from the layout of a real photo mask. This difference may cause technical problems as described with respect to the related art.

Still referring to FIG. 4, critical point data 190 defining information on the weak points of the fabricated photo mask may be extracted using an aerial image measurement system (AIMS) 180. In at least this example embodiment, the critical point data 190 may be obtained by analyzing the actual fabricated photo mask (e.g., created using photo mask operation 160). The critical point data 190 may provide more precise information regarding the pattern transfer fidelity of the photo mask than the weak point data 170 obtained based on the mask layout data 140.

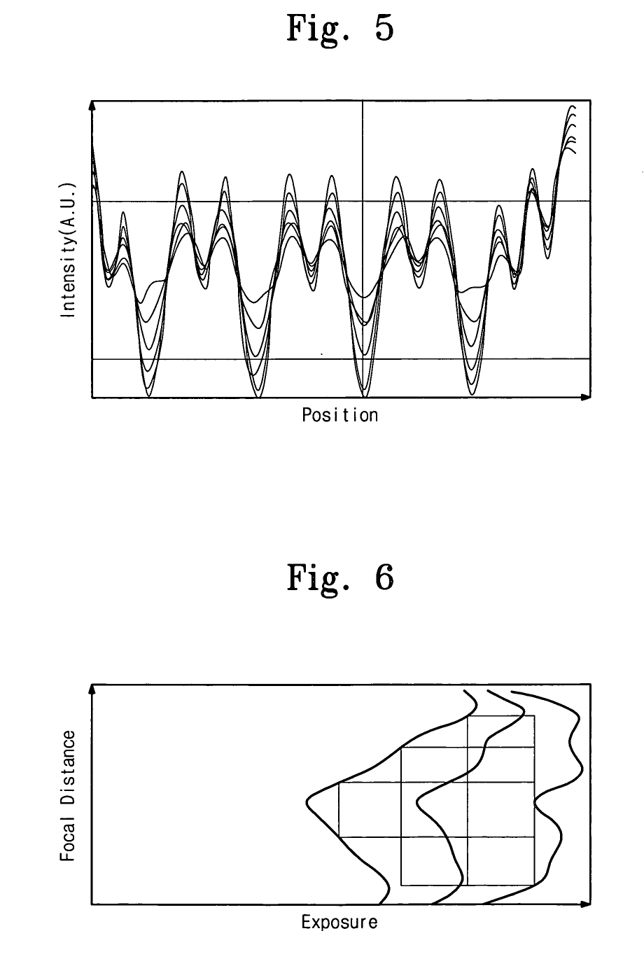

The AIMS 180 may measure the aerial image of the real photo mask. For example, the AIMS 180 may measure the optical property (e.g., intensity) of exposure beams passing through the fabricated photo mask while exposing the photo mask to light under real exposure conditions. In at least this example, the aerial image may be represented as a graph showing the measured optical property of exposure beams with respect to position and exposure conditions (e.g., focal distance). FIG. 5 is a graph showing an example aerial image of the photo mask.

Referring back to FIG. 4, in at least one example embodiment, the AIMS 180 may use weak point data 170 as input data to extract critical point data 190. For example, the AIMS 180 may measure the aerial image of the fabricated photo mask at weak points defined by the weak point data 170. The aerial image may be compared with the IC layout data 120 to extract the critical point data 190. In at least this example embodiment, the critical point data 190 may have a smaller number of points liable and/or susceptible to failures than the weak point data 170.

Still referring to FIG. 4, in another example embodiment, the critical point data 190 may be extracted by comparing the aerial image with the IC layout data 120 throughout the photo mask. In at least this example, the accuracy of the critical point data 190 may be increased relative to the above-described methods based solely on the weak point data 170.

A preliminary evaluation operation 200 may be performed based on at least the critical point data 190. In the preliminary evaluation operation 200, the quality (e.g., a critical dimension (CD) and/or a process margin) of the photo mask may be evaluated by analyzing the critical point data 190. FIG. 6 is a graph showing example results obtained by analyzing a process margin using the aerial image shown in FIG. 5.

In at least this example, because the critical point data 190 used in the preliminary evaluation operation 200 corresponds to the results obtained by analyzing the fabricated photo mask as discussed above, the preliminary evaluation operation 200 may provide relatively precise and/or accurate information regarding the quality of the fabricated photo mask. In at least this example embodiment, if the fabricated photo mask falls below a threshold standard (e.g., fails the preliminary evaluation), a new photo mask may be fabricated by analyzing the critical point data 190. On the other hand, if the fabricated photo mask passes the threshold standard (e.g., passes the preliminary evaluation), a wafer-level evaluation operation 210 may be performed. In the wafer-level operation 210 the quality of the fabricated photo mask may be evaluated on a wafer level.

In at least one example embodiment, if the photo mask fails the preliminary evaluation operation 200, the analysis results regarding the critical point data 190 may be utilized to update the OPC model 110 for the OPC operation 130. Alternatively or in addition to the above, the IC layout data 120 may be updated based on the analysis results regarding the critical point data 190. In at least one example embodiment, the IC layout data 120 may be updated based on the analysis results regarding the weak point data 170 and/or the aerial image of the photo mask. This re-fabrication of the photo mask may include preparing new mask layout data and/or new weak point data. For example, whether a new photo mask is to be fabricated or not may be determined by the wafer-level evaluation operation 210, and in some example embodiments, not the preliminary evaluation operation 200.

The wafer-level evaluation operation 210 may include forming actual photoresist patterns on the wafer by a lithography process using the fabricated photo mask and analyzing the profile of the formed photoresist patterns. In this example, if the fabricated photo mask satisfies a threshold condition, the photo mask may be continuously used in a lithography process 220 for fabrication. The critical point data 190 may serve as information for determining inspection positions during an inspection on the result of the lithography process 220. Considering the critical point data 190 contains information regarding weak points selected from the weak points defined by the weak point data 170 from the analysis of the real photo mask, the use of the critical point data 190 may enhance and/or improve efficiency of inspection.

On the other hand, if the fabricated photo mask does not satisfy the threshold condition, the photo mask may be re-fabricated. In at least one example embodiment, because the new mask layout data and new weak point data are prepared through the preliminary evaluation 200, time consumed during re-fabrication of the photo mask may be reduced. As described above, a relatively long amount of time may be needed from the photo mask fabrication operation 160 to the wafer-level evaluation operation 210. Therefore, in at least one example embodiment, time required for developing products and/or a preparation period for producing products may be reduced.

Re-fabrication of the photo mask may include forming a photoresist pattern using the initially fabricated photo mask and undergoing an etching process using the photoresist pattern as an etch mask. In this example, by analyzing the result of the etching process, information regarding the layout of the photo mask and/or an etching profile (e.g., the relation between the layout of the photo mask and the etching profile) may be extracted. Information regarding the etching profile may be derived from an after-development inspection (ADI) and/or an after-cleaning inspection (ACI) and may be used during the ORC 150 and/or the updating of the IC layout data 120.

For example, if development of the photoresist pattern and an after-etch cleaning process are independent of the appropriateness of the photo mask layout, the information regarding the etching profile may be considered as an independent variable during the re-fabrication of the photo mask, thereby facilitating re-fabrication of the photo mask.

As in the preliminary evaluation operation 200, the result of the analysis of the critical point data 190 may be utilized to update the OPC model 110 and/or the IC layout data 120 during re-fabrication of the photo mask. Similarly, updating of the OPC model 110 and/or the IC layout data 120 may be conducted based on the result of the analysis on the weak point data 170 and/or the aerial image of the photo mask.

In at least one other example embodiment, when a failure (e.g., serious failure) is found in the preliminary evaluation operation 200, re-fabrication of the photo mask may be performed without the wafer-level evaluation operation 210. In this example, a time required to fabricate a photo mask may be reduced relative to the related art.

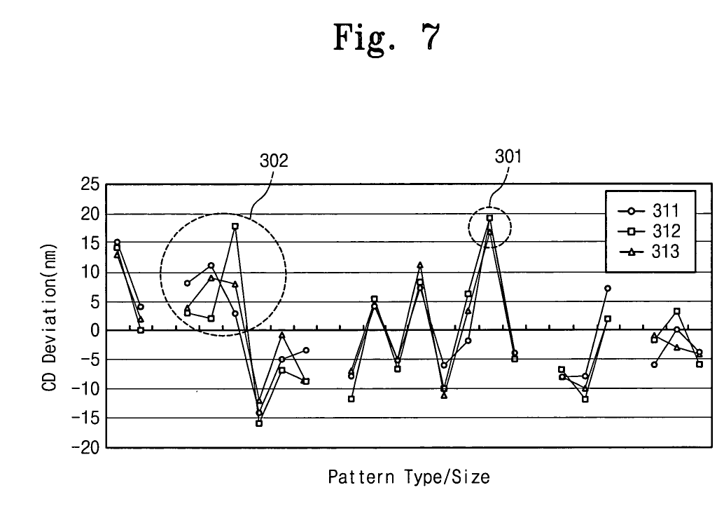

FIG. 7 is a graph illustrating an example method of analyzing critical point data (e.g., CD deviations of patterns with respect to various types and sizes), according to an example embodiment. Referring to FIG. 7, an abscissa denotes the types and sizes of the patterns and an ordinate denotes the CD deviations of the patterns. In this example, the CD deviation of the pattern refers to a difference between the CD of the pattern measured using the AIMS 180 and the CD of the pattern defined by the IC layout data 120. The photo mask used for the measurement of the CD deviation may include first, second and/or third lower regions with the same layout. Reference numerals 311, 312 and 313 in FIG. 7 refer to CD deviations measured at the same position of the first, second and third lower regions, respectively.

Still referring to FIG. 7, when an allowed CD deviation is about 15 nm, a first group 301 departs from the allowed CD deviation in the three lower regions, while a second group 302 is within the range of the allowed CD deviation except at one measured position of the second lower region 312. In this example, the CD deviations of the patterns belonging to the first group 301 converge to a value. For example, the dispersion of the CD deviations of the patterns belonging to the first group 301 may be relatively small. On the other hand, the dispersion of the CD deviations of the patterns belonging to the second group 302 may be greater than that of the CD deviations of the patterns belonging to the first group 301.

In this example, if the OPC operation 300 is applied to the first, second and third lower regions, a difference in the dispersion of the CD deviations may be indicative of the cause of the CD deviations. For example, when the CD deviations of the patterns in the three lower regions 311, 312 and 313 have a relatively small dispersion, but depart from the allowed standard, the failure is determined to have resulted from the OPC operation 130. In this example, the OPC model 110 may be changed. On the other hand, when the CD deviations of the patterns in the three lower regions 311, 312 and 313 have a relatively large dispersion, this phenomenon (e.g., failure) is determined to have occurred during the fabrication of the photo mask. As a result, even if one point of the second group 302 departs from the allowed CD deviation, the OPC model 110, the IC layout data 120 and/or the mask layout data 140 need not be changed, but a process deviation caused during the fabrication 160 of the photo mask may be removed.

According to at least some example embodiments, the cause of the failure may be found by analyzing the aerial image of the photo mask. In this example, considering the aerial image is derived from the fabricated photo mask, the aerial image used for analyzing information reflecting problems caused during the fabrication 160 of the photo mask. Therefore, the related art case without the operations of comparing the aerial image of the fabricated photo mask with the IC layout data 120 and analyzing the comparison result may not obtain the aforementioned effect.

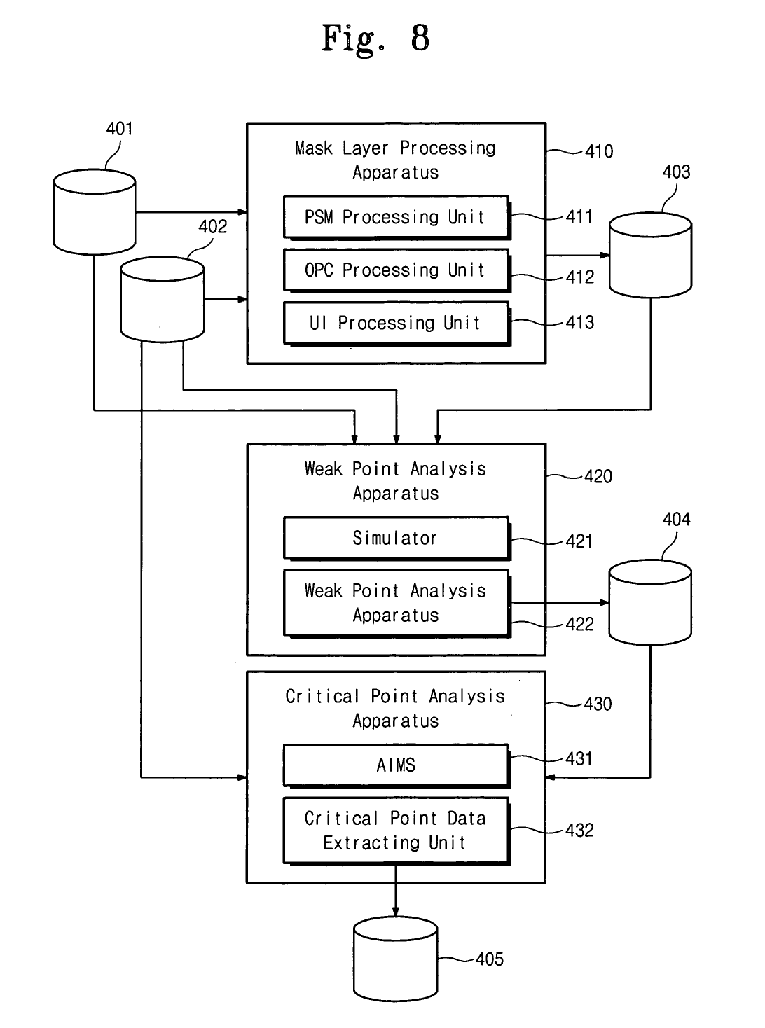

FIG. 8 is an apparatus, according to an example embodiment. The apparatus of FIG. 8 may be used to construct diagrams explaining a photo mask fabrication system.

Referring to FIG. 8, a photo mask fabrication system, according to an example embodiment, may include a mask layout processing apparatus 410, a weak point analysis apparatus 420 and/or a critical point analysis apparatus 430. The mask layout processing apparatus 410 may include a PSM processing unit 411, an OPC processing unit 412 and/or a user interface (UI) processing unit 413. The mask layout processing apparatus 410 may be connected to an OPC model database 401 and an IC layout database 402 through at least one communication apparatus. The OPC model database 401 may store OPC models and the IC layout database 401 and 402 may store IC layout data. Although shown as separate databases, the OPC model database 401 and the IC layout database 402 may be included in a single database.

The PSM processing unit 411 may introduce a PSM region to the IC layout data. The PSM region may enable features with a dimension smaller than the wavelength of light passing through a photo mask to be printed on a target pattern. The UI processing unit 413 may enable a user to observe and/or correct at least some or all of patterns defined by the IC layout data.

The OPC processing unit 412 may correct an IC layout to suppress and/or prevent distortion of images due to an OPE. For this function, the OPC processing unit 412 may include a fragment processor, which may divide patterns included in the IC layout into a plurality of fragments, and an OPC controller, which may perform an OPC process on each of the fragments. The OPC controller may correct fragments based on an OPC model selected out of the OPC model database 401 to compensate for distorted (e.g., nonlinear distortion) caused by optical diffraction and/or a resist process effect. This OPC process may make use of a simulation to predict the shape of the target pattern. The IC layout data corrected by the OPC processing unit 412 may constitute mask layout data stored in a mask layout database 403. The mask layout database 403 may be separate from or combined with the OPC model database 401 and/or the IC layout database 402.

The weak point analysis apparatus 420 may include a simulator 421 and/or a weak point data extracting unit 422. The simulator 421 may simulate predicting the layout of a photo mask to be fabricated based on the mask layout data. The weak point data extracting unit 422 may compare the layout of the photo mask predicted by the simulator 421 with the IC layout data to generate a comparison result, analyze the comparison result and extract weak point data. To perform this function, the weak point data extracting unit 422 may be connected to the mask layout database 403 and the IC layout database 402 through at least one communication apparatus.

The comparison and/or analysis operations for extracting the weak point data may include inspecting if a difference between the predicted layout of the photo mask and the IC layout satisfies a threshold standard and extracting information on the coordinates, CDs and/or margins of points that do not satisfy the standard. Also, the weak point data may be stored in a weak point database 404. In this example, a communication apparatus may be located between the weak point analysis apparatus 420 and the weak point database 404. The weak point database 404 may be separate from or combined with the OPC model database 402, the IC layout database 402 and/or the mask layout database 403.

The critical point analysis apparatus 430 may include an AIMS 431 and a critical data extracting unit 432. The AIMS 431 may to measure the aerial image of a fabricated photo mask and compare the IC layout with the aerial image of the photo mask. In this example, the AIMS 431 may utilize the weak point data as input data to improve measurement efficiency. For example, the AIMS 431 may compare the IC layout with the aerial image of the photo mask to generate a comparison result and analyze the comparison result at weak points defined by the weak point data. These comparison and analysis operations may be performed by the critical point extracting unit 432, and the analysis result may be stored as critical point data in a critical data database 405. In this example, the critical point analysis apparatus 430 may be connected to the IC layout data 402, the weak point database 404 and/or the critical point database 405 through at least one communication apparatus. The critical database 405 may be separate from or combined with the OPC model database 401, the IC layout database 402, the mask layout database 403 and/or the weak point database 404.

According to at least some example embodiments as described herein, weak point data may be obtained by comparing the IC layout and the mask layout, and critical point data may be obtained by analyzing the aerial image of the fabricated photo mask based on the weak point data. Considering that the aerial image may be derived from the real photo mask, the critical point data obtained using the aerial image may reflect actual information regarding the fabricated photo mask. Therefore, the critical point data may provide more accurate information on the photo mask.

According to at least some example embodiments, the critical point data may be obtained by selectively analyzing weak points defined by the weak point data. By selectively analyzing the weak points, the analysis of the aerial image may improve or substantially improve efficiency.

According to at least some example embodiments, the quality of the photo mask may be evaluated (e.g., preliminarily evaluated) based on critical point data to shorten or substantially shorten delay time required for fabricating a new photo mask. In addition, the critical point data may be utilized for updating the OPC model used for the OPC operation and/or the IC layout data. These evaluation and/or updating operations may be enabled because the critical point data results from the actual photo mask.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method of fabricating a photo mask, comprising:
generating mask layout data for defining a layout of patterns to be formed on a photo mask;
generating weak point data indicative of predicted weak points of a photo mask based on the mask layout data;
fabricating a photo mask based on the mask layout data; and
extracting critical point data indicative of information on weak points of the fabricated photo mask by analyzing an aerial image of the fabricated photo mask based on the weak point data.

2. The method of claim 1, wherein the generating of the mask layout data includes,
generating circuit layout data, and
modifying the circuit layout data using a correction model.

3. The method of claim 2, wherein the generating the mask layout data further includes,
phase-shift mask processing the circuit layout data.

4. The method of claim 1, wherein the generating of the weak point data includes,
predicting the layout of the photo mask based on the mask layout data, and
generating the weak point data by comparing the predicted layout of the photo mask with circuit layout data to generate a comparison result and analyzing the comparison result, wherein
the weak point data includes information on at least one of coordinates, pattern sizes and size margins of points violating an optical rule.

5. The method of claim 1, wherein the analyzing of the aerial image of the photo mask is performed using a measurement system including a communication apparatus capable of accessing the weak point data and using the weak point data as input data.

6. The method of claim 1, wherein the extracting of the critical point data includes,
extracting information on at least one of coordinates, pattern sizes and size margins of points violating an optical rule by comparing the aerial image of the photo mask with the circuit layout data to generate a comparison result, and analyzing the comparison result at the weak points defined by the weak point data.

7. The method of claim 1, further including,
evaluating the quality of the fabricated photo mask by analyzing the critical point data, and
evaluating the quality of the photo mask on a wafer level through a lithography process using the photo mask.

8. The method of claim 7, wherein if the quality of the photo mask falls below a threshold, at least one of a correction model and circuit layout data is updated based on at least one of the weak point data, the critical point data and the aerial image of the photo mask.

9. The method of claim 7, wherein if the quality of the photo mask falls short of a threshold standard on the wafer level, at least one of a correction model and circuit layout data is updated using at least one of the weak point data, the critical point data and the aerial image of the photo mask.

10. The method of claim 7, further including,
performing a lithography process using the fabricated photo mask when a quality of the photo mask passes a threshold standard, the critical point data being used as data for defining inspection positions during an inspection of the result of the lithography process.

11. A photo mask fabrication system comprising:
at least one database for storing circuit layout data and mask layout data;
a modification apparatus for modifying the circuit layout data to generate the mask layout data;
a weak point analysis apparatus for generating weak point data based on the mask layout data; and
a critical point analysis apparatus for generating critical point data based on the weak point data.

12. The system of claim 11, wherein the weak point analysis apparatus generates weak point data based on the mask layout data, the circuit layout data and a correction model.

13. The system of claim 11, wherein the weak point analysis apparatus generates weak point data based on the mask layout data, the circuit layout data, a correction model and analysis results associated with a previous critical point evaluation.

14. The system of claim 11, wherein the at least one database includes,
a first database for storing the circuit layout data, and
a second database for storing the mask layout data.

15. The system of claim 11, wherein the modifying the circuit layout data further includes,
dividing patterns of the circuit layout data into a plurality of fragments, and
correcting each of the plurality of fragments to generate the mask layout data.

16. The system of claim 15, wherein each of the plurality of fragments is corrected based on a correction model.

17. The system of claim 11, wherein the weak point analysis apparatus includes,
a simulator for predicting a layout of a photo mask, and
a weak point data generating unit for comparing the predicted layout of the photo mask with the circuit layout data to generate a comparison result and analyzing the comparison result to generate the weak point data.

18. The system of claim 11, wherein the at least one database stores a plurality of correction models, and the modification apparatus is connected to the at least one database through the at least one communication apparatus.

19. The system of claim 18, wherein the at least one database includes,
a first database for storing the layout data,
a second database for storing the mask layout data, and
a third database for storing the correction models.

20. The system of claim 11, wherein the critical point analysis apparatus includes,
a measurement apparatus for measuring an aerial image of the photo mask, and
a critical point data generating unit for selectively comparing the aerial image with the circuit layout data to generate a comparison result and analyzing the comparison result at weak points defined by the weak point data.
